(19) United States
(12) Patent Application Publication
(10) Pub. No.: US 2007/0108464 A1
(43) Pub. Date: May 17, 2007

(54) LED PACKAGE WITH IMPROVED HEAT DISSIPATION AND LED ASSEMBLY INCORPORATING THE SAME

(76) Inventor: Sang-Jin Seol, Seoul (KR)

Correspondence Address: SUGHRUE MION, PLLC, 2100 PENNSYLVANIA AVENUE, N.W., SUITE 800, WASHINGTON, DC, 20037, US

(21) Appl. No.: 11/560,975

(22) Filed: Nov. 17, 2006

(30) Foreign Application Priority Data
Nov. 17, 2005 (KR) 10-2005-0110474

(51) Int. Cl. H01L 33/00; H01L 29/24

(52) U.S. Cl. 257/100

(57) ABSTRACT

An LED package with improved heat dissipation and an LED assembly incorporating the same. The LED package includes a base made of a thermally conductive polymer; a pair of terminals formed on an upper side of the base; a LED chip electrically connected to the terminals; and a transparent encapsulant arranged on the upper side of the base to encapsulate the LED chip. With the package base formed of a thermally conductive polymer, the LED package has improved heat dissipation performance.

### CROSS REFERENCE TO RELATED APPLICATION

This application claims the benefit of Korean Patent Application No. 10-2005-0110474 filed on Nov. 17, 2005, in the Korean Intellectual Property Office, the disclosure of which is incorporated herein by reference.

### BACKGROUND OF THE INVENTION

1. Field of the Invention

The present invention relates to a Light Emitting Diode (LED) and, more particularly, to an LED package having a package base made of a thermally conductive polymer to improve heat dissipation performance and an LED assembly incorporating the same.

2. Description of the Related Art

To date, LEDs are being adopted as a light source of backlight units for use with lighting devices and Liquid Crystal Displays (LCDs).

Such LEDs are semiconductor devices that are activated in response to electric current to generate various colors of light. The color of light generated by an LED is mainly determined by chemical components of LED semiconductor. Such LEDs have several merits such as longer lifetime, lower driving voltage, better initial activation characteristics, higher vibration resistance and higher tolerance on repetitive power switching over conventional lighting devices using filaments, and thus demand for them is gradually on the rise.

However, an LED chip does not perfectly convert current into light and thus generates heat at a considerable amount. The heat if not dissipated or radiated properly may give stress to internal elements of the LED thereby to shorten the lifetime of the LED. To solve this problem, the LED dissipates or radiates heat to the outside by using a heat dissipation or radiation structure having metal lead frames.

An example of such a heat dissipating structure is shown in FIGS. 1 and 2.

Referring to FIG. 1 first, an LED package 10 includes a thermal conducting member 14 with an LED chip 12 seated thereon. The thermal connecting member 14 also functions as heat guide means. The LED chip 12 is powered via a pair of wires 16 and a pair of leads 18. An encapsulant 20 of typically silicone is arranged to encapsulate the LED chip 12, and a lens 22 is capped on the encapsulant 20. A housing 24 is arranged around the thermal connecting member 14 to support the thermal connecting member 14 and the leads 18.

The LED package 10 shown in FIG. 1 is mounted on a metal board 30 acting as a heat sink as shown in FIG. 2 thereby to constitute an LED assembly. A thermally conductive pad 36 such as solder is interposed between the heat conducting member 14 of the LED package 10 and a metal body 32 of the main board 30 to promote heat conduction between them. In addition, the leads 18 are also stably connected to a circuit pattern 34 on the metal body 32 of the metal board 30.

However, this type of heat dissipation structure has drawbacks as follows. First, it is too complicated to be automated and has a number of parts to be assembled together, which inevitably raise manufacturing cost. Moreover, this structure can be hardly reduced in size owing to its complicity and the large number of parts.

### SUMMARY OF THE INVENTION

The present invention has been made to solve the foregoing problems of the prior art and therefore an aspect of the present invention is to provide an LED package with improved heat dissipation performance owing to a package base formed of a thermally conductive polymer and an LED assembly incorporating the same.

Another aspect of the invention is to improve the reflectivity of the LED package by providing a reflector around an LED chip.

Further another aspect of the invention is to insert the LED package at least partially into a metal board in order to further enhance heat dissipation efficiency.

According to an aspect of the invention, an LED package includes a base made of a thermally conductive polymer; a pair of terminals formed on an upper side of the base; a LED chip electrically connected to the terminals; and a transparent encapsulant arranged on the upper side of the base to encapsulate the LED chip.

The LED package may further include a wall extended from a periphery of the upper side of the base beyond the LED chip to form a recess surrounding the LED chip, where the transparent encapsulant is filled.

The LED package may further include a reflector applied on an inner surface of the wall of the base.

Preferably, the reflector comprises metal. More preferably, the reflector comprises at least one selected from the group consisting of Ag, Al, Au, Cu, Pd, Pt, Rd and alloys thereof. The reflector may comprise a deposit. The LED package may further include an insulating layer formed on a predetermined area in an upper side of the terminals to insulate the reflector from the terminals.

Preferably, the reflector comprises a metal film bonded to an inner surface of the wall of the base.

The wall may be integral with the base or comprise a separate body bonded to the base.

According to another aspect of the invention, an LED assembly includes a metal board having a circuit pattern formed on an upper side thereof and an LED package as described above, mounted on the upper side of the metal board. The terminals of the light emitting diode package are electrically connected to the circuit pattern.

Preferably, the metal board has a recess for receiving at least a part of the light emitting diode package.

The LED assembly may further include an upper board attached to the upper side of the metal board, the upper board receiving at least a part of the light emitting diode package to expose the transparent encapsulant.

Preferably, the metal board may be at least a part of a board of a backlight unit on which the light emitting diode assembly is mounted as a light source.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional perspective view illustrating an LED package of the related art;

FIG. 2 is a cross-sectional view illustrating the LED package of FIG. 1 mounted on a metal board;

FIG. 3 is a perspective view illustrating an LED package of the invention;

FIG. 4 is a cross-sectional view illustrating the LED package of FIG. 3 taken along the line 4-4 of FIG. 3, mounted on a metal board;

FIG. 5 is a cross-sectional view illustrating the LED package of FIG. 3 taken along the line 5-5 of FIG. 3, received in a recess of a metal board;

FIG. 6 is a cross-sectional view illustrating an LED package according to another embodiment of the invention;

FIG. 7 is a cross-sectional view illustrating a variation to the LED package shown in FIG. 6;

FIG. 8 is an exploded cross-sectional view of the LED package shown in FIG. 7;

FIG. 9 is an exploded cross-sectional view illustrating another variation to the LED package shown in FIG. 6;

FIG. 10 is a perspective view illustrating an LED assembly of the invention;

FIG. 11 is a perspective view illustrating an LED assembly according to another embodiment of the invention;

FIG. 12 is an exploded cross-sectional view illustrating an LED assembly according to further another embodiment of the invention;

FIG. 13 is an assembled cross-sectional view of the LED assembly shown in FIG. 13; and

FIG. 14 is a side elevation view illustrating an LED assembly according to still another embodiment of the invention, shown partially in cross-section.

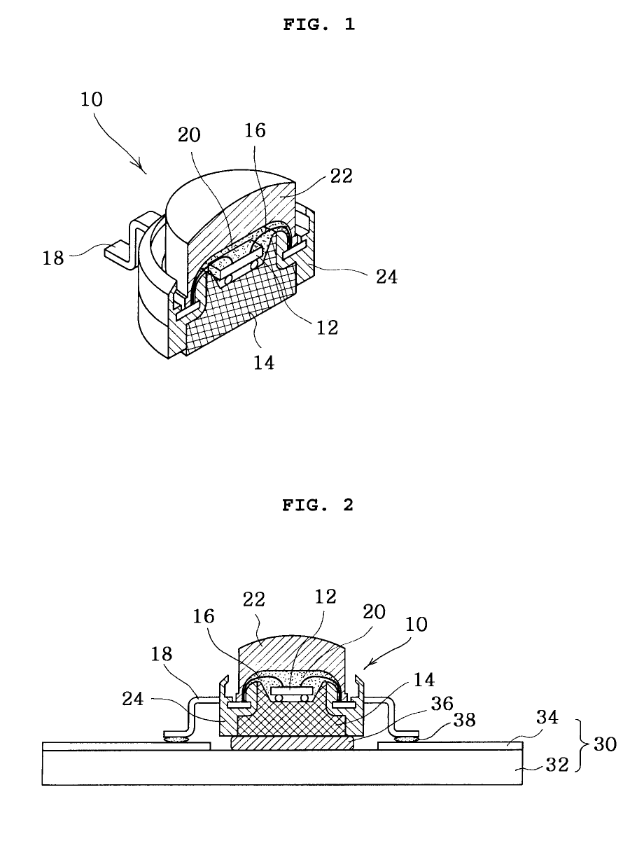

### DETAILED DESCRIPTION OF THE PREFERRED EMBODIMENT

The present invention will now be described more fully hereinafter with reference to the accompanying drawings, in which exemplary embodiments of the invention are shown.

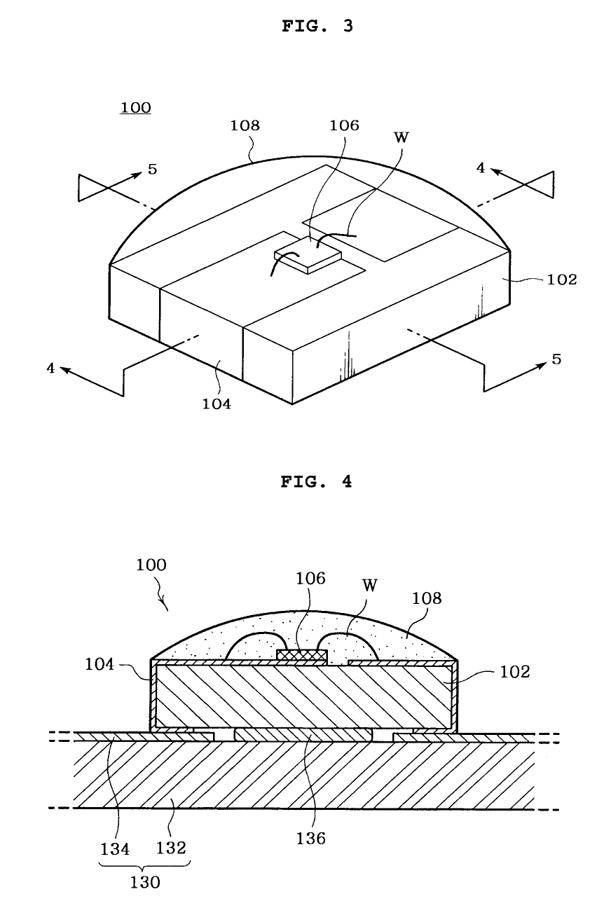

FIG. 3 is a perspective view illustrating an LED package 100 of the invention, and FIG. 4 is a cross-sectional view illustrating the LED package 100 taken along the line 4-4 of FIG. 3, mounted on a metal board 130.

Referring to FIGS. 3 and 4, the LED package 100 of this embodiment includes a base 102 made of a thermally conductive polymer, a pair of terminals 104 formed on an upper side of the base 102, an LED chip 106 attached to one of the terminals 104 and electrically connected to both of the terminals 104 via wires W, and a transparent encapsulant 108 arranged on the upper side of the base 102 to encapsulate the LED chip 106.

The LED package 100 has an external appearance similar to a common surface mounted LED package. However, unlike the common LED package, the LED package 100 of this embodiment has the base 102 made of a thermally conductive polymer.

The term “thermally conductive polymer” indicates a polymer that is specially fabricated to have an excellent thermal conductivity. It is generally known that the thermally conductive polymer has a thermal conductivity of 1 W/mK or more.

Representative examples of the thermally conductive polymer include Coolpoly® available from Cool Polymer Inc of the United States and LUCON 9000™ available from LG Chem, Ltd. of Korea.

Coolpoly® has a thermal conductivity in the range from 10 W/mK to 100 W/mK, which is a very high thermal conductivity in view of Al having a thermal conductivity of about 200 W/mK and common plastics have a thermal conductivity of about 0.2 W/mK. Coolpoly® also has relatively good workability such as formability.

LUCON 9000™ has a thermal conductivity in the range from 1 W/mK to 50 W/mK which is relatively lower than that of Coolpoly® but still shows a performance about 50 times or more with respect to common plastics. It is also known that LUCON 9000™ has better formability than Coolpoly®.

Considering desired thermal conductivity and formability, it is preferable that the thermally conductive polymer has a thermal conductivity of 10 or more.

With the base 102 made of the thermally conductive polymer, heat generated from the LED chip 106 is conducted effectively to the outside also via the base 102.

As shown in FIG. 4, the LED package 10 of this embodiment is mounted on a metal board 130 acting as a heat sink thereby to constitute an LED assembly. The metal board 130 includes a board body 132 made of metal and a circuit pattern 134 formed on the board body 132 with an insulating pattern (not shown) interposed between the board body 132 and the circuit pattern 134.

The terminals 104 are connected to the circuit pattern 134 to conduct heat to the board body 132 through the pattern 134 in a similar manner as in the prior art. In the meantime, the heat conducted through the terminals 104 to the package base 102 is conducted to the board body 132 of the metal board 132 through the contact between the base 102 and the metal board body 132. That is, as shown in FIG. 4, a thermally conductive pad 136 may be interposed between the underside of the LED package base 102 and the top surface of the metal board body 132 to ensure heat conduction between the package base 102 and the board body 132. In this manner, the LED package base 102 having excellent thermal conductivity can completely conduct heat from the terminals 104 to the metal board body 132 so that the LED chip 106 can maintain a suitable temperature.

Comparing FIG. 4 with FIG. 2, the heat dissipation structure of this embodiment is simplified but can obtain a heat dissipation performance substantially the same as that of the prior art. This results from excellent thermal conductivity of the LED package base 102 as described above.

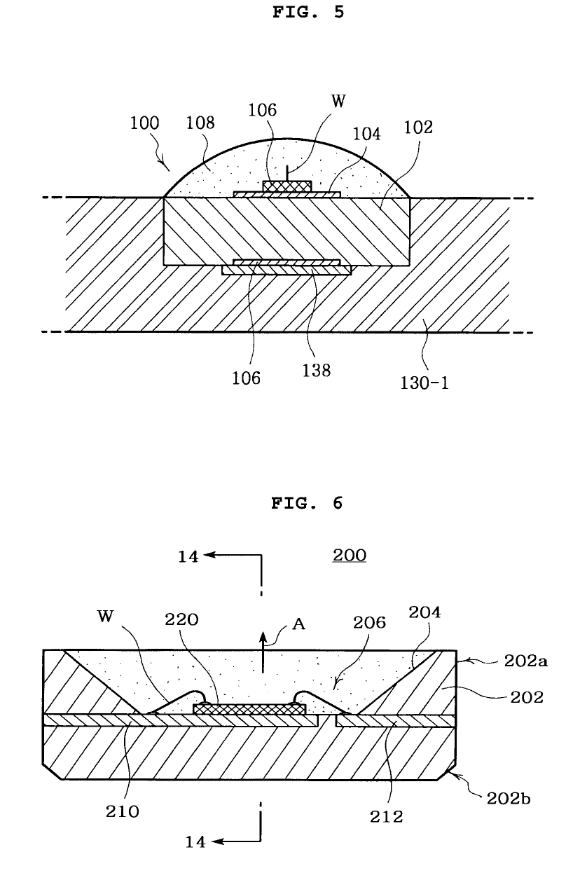

Heat dissipation effect through direct contact between the LED package base 102 and the metal board 130-1 will now be described with reference to FIG. 5 that is a cross-sectional view illustrating the LED package 100 of FIG. 3 taken along the line 5-5 of FIG. 3, received in a recess of a metal board 130-1. A circuit pattern 138 connected with the terminals 106 of the LED package 100 is arranged on the recess of the metal board 130-1 with an insulating layer (not shown) interposed between the circuit pattern 138 and a body of the metal board 130-1.

Alternatively, the circuit pattern 138 may be arranged on the sidewall of the recess or the top surface of the metal board 130-1 to be connected with the terminals 106 of the LED package 100.

This allows the LED package base 102 to be in direct contact with the metal board 150. With the LED package 100 received in the recess of the metal board 130-1, any heat generated from the LED chip 102 is conducted through the LED package base 102 to the metal board 150 as described above. Such heat conduction is easily carried out owing to high thermal conductivity of the LED package base 102 as described above, and thus the LED chip 106 can maintain a suitable temperature.

Effective heat dissipation performance like this through direct contact between the LED package base 102 and the metal base 150 cannot be realized by the prior art.

While it has been illustrated in FIG. 5 that only the base 102 of the LED package 100 is received in the metal board 130-1, it is not intended to limit the invention. Rather, the LED package 100 may be received in the metal board 130-1 to the extent that the LED chip 106 is positioned under the top surface of the metal board 130-1. With this arrangement, the sidewall of the recess of the metal board 130-1 can act as a reflector so that light of the LED chip 106 can be guided upward more effectively.

FIG. 6 is a cross-sectional view illustrating an LED package 200 according to another embodiment of the invention.

Referring to FIG. 6, the LED package 100 of this embodiment includes a base 202 made of a thermally conductive polymer, first and second terminals 210 and 212 formed on a portion of the base 202, an LED chip 220 attached to the first terminal 210 and electrically connected to both of the terminals 210 and 212 via wires W, and a transparent encapsulant 230 arranged on the upper side of the base 202 to encapsulate the LED chip 220.

The package base 202 is divided into an upper base part 202a and a lower base part 202b across the terminals 210 and 212. The upper base part 202a is in the form of a wall with a recess 206 formed therein. The wall has an inner surface 204 acting as a reflector to guide light of the LED chip 220 in the direction of arrow A.

The LED package 200 of this structure is configured suitable to project light from LED chip 220 in a specific direction. Since the LED package 200 of this structure is generally required of high power, the LED chip 200 generates a large amount of heat. Thus, the package base 202 made of a thermally conductive polymer as described above is particularly advantageous to radiate or dissipate the heat to the outside.

The LED package 200 of this embodiment can be also applied in the form of FIG. 4 or 5 to conduct heat more effectively to the metal board.

Alternatively, the LED package of FIG. 6 may be configured to be flat in a vertical direction of the paper as shown in FIG. 14. Such an LED package 200 (see FIG. 14) is also referred to as a side-view LED package which also can effectively dissipate or radiate heat to a metal board carrying the LED package 200.

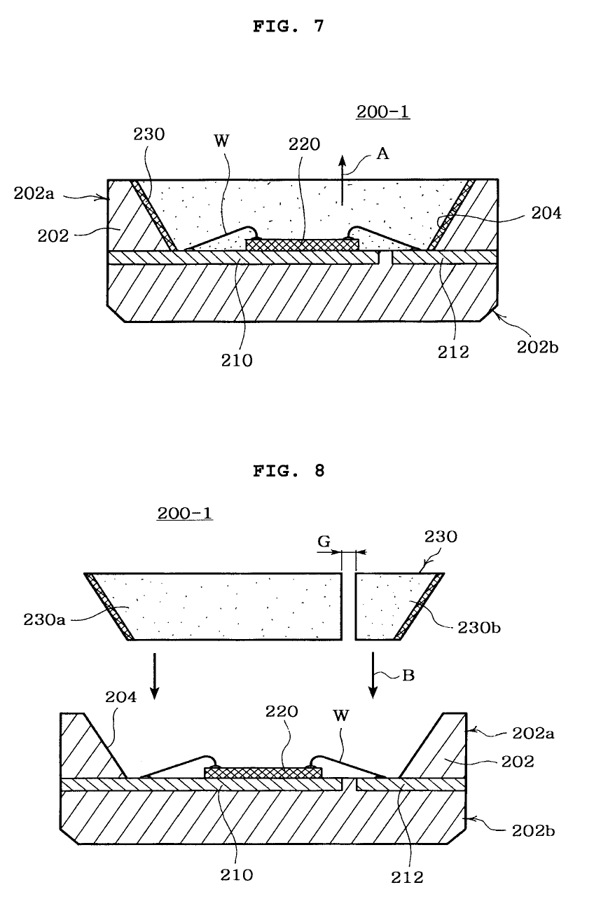

FIG. 7 is a cross-sectional view illustrating an LED package 200-1 that is a variation to the LED package 200 shown in FIG. 6, and FIG. 8 is an exploded cross-sectional view of the LED package 200-1 shown in FIG. 7.

Referring to FIGS. 7 and 8, the LED package 200-1 is substantially the same as the LED package 200 shown in FIG. 6 except for a reflector 230 applied to an inner surface 204 of the LED package 200. Accordingly, the like reference signs are used to designate the like components, and the detailed description thereof will be omitted.

The reflector 230 made of metal is configured to cover substantially the entire inner surface 204 of the wall of the LED package base 202, and at the bottom end thereof, contacts the terminals 210 and 212. The reflector 230 is divided into two reflector parts 230a and 230b with a predetermined gap G so that the reflector part 230a contacts the terminal 210 and the reflector part 230b contacts the terminal 212. With this arrangement, the terminals 210 and 212 in contact with the reflector 230 may be protected from short-circuit. Of course, it is also possible to make the reflector 230 not to contact the terminals 210 and 212, that is, the reflector 230 to be separated from the terminals 210 and 212 at a predetermined interval. In such a case, it is not required to divide the reflector 230 into the reflector parts 230a and 230b with the gap G.

In this embodiment, the reflector 230 is manufactured of a high reflectivity metal, and preferably, of at least one selected from the group consisting of Ag, Al, Au, Cu, Pd, Pt, Rd and alloys thereof.

In addition, the reflector 230 is provided in the form of a sheet metal or metal film, and attached to the inside wall 204 of the LED package base 202 via adhesive and the like. Alternatively, the reflector 230 may be attached to the inside wall 204 of the LED package base 202 via interference fit.

With this arrangement, the reflector 230 can reflect light of the LED chip 220 in an upward direction as designated with arrow A, thereby improving light efficiency of the LED package 200-1. In addition, the reflector 230 reflects light so as not to be absorbed by the inside wall 204, thereby to insulate heat that otherwise may be applied to the interior of the LED package 200-1.

Alternatively, the reflector 230 may be provided by deposition. That is, the reflector 230 may be formed by bonding high reflectivity metal particles to the inner surface 204 of the upper base part 202a of the LED package base 202 through sputtering or electron beam process.

In this case, the reflector 230 is formed in the form of a film, and possibly, to a thickness of several Å to several μm. However, the thickness of the reflector 230 is not specifically limited but may be set to any value that can effectively reflect light from the LED chip 220 in the direction of arrow A.

In this case, it is preferable to previously form an insulating layer (not shown) on regions where the inner surface 204 contacts the terminals 210 and 212 so that the reflector 230 does not contact the terminals 210 and 212.

With this arrangement, the reflector 230 can reflect light from the LED chip 220 in the upward direction as indicated with arrow A, thereby improving light efficiency of the LED package 200-1. The reflector 230 also reflects light not to be absorbed into the inner surface 204, thereby to insulate heat that may otherwise be applied to the interior of the LED package 200-1. Furthermore, the reflector 230 can be arranged continuously on the entire inner surface 204 of the upper base part 202a of the base 202, thereby to improve reflection efficiency over the embodiment shown in FIG. 6.

As another alternative, the reflector 230 may be made of a high reflectivity polymer. That is, the reflector 230 may be provided for example by applying the high reflectivity polymer on the inner surface 204 of the upper base part 202a. In this case, it is not required to separate the reflector 230 into the reflector parts 230a and 230b as in FIG. 8.

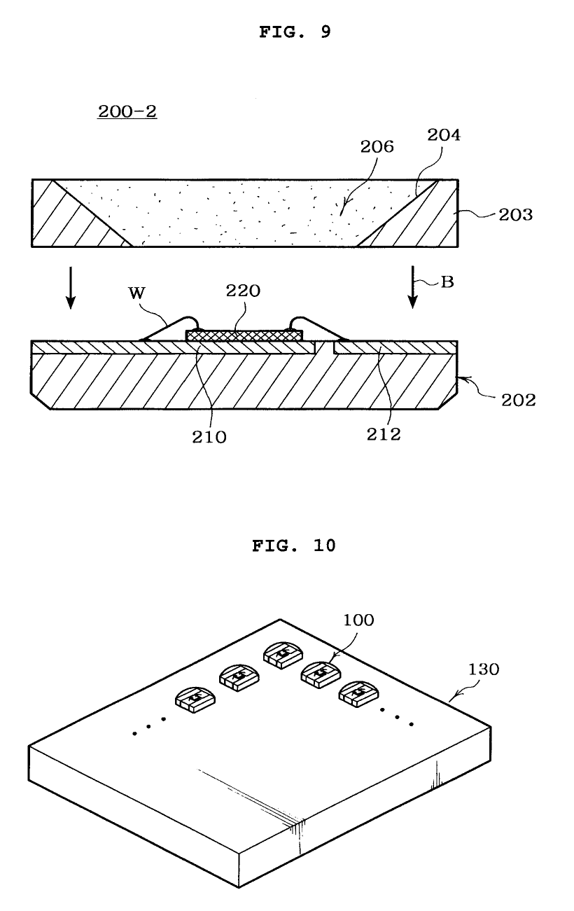

FIG. 9 is an exploded cross-sectional view illustrating another variation to the LED package 200-2 shown in FIG. 6. The LED package 200-2 shown in FIG. 9 has a base made by attaching an upper base part 203 to a lower base part 202.

In this arrangement, the lower base part 202 is made of a thermally conductive polymer as described above, but the upper base part 203 is made of a common polymer. The upper base part 203 integrally bonded to the lower base part 202 via for example adhesive makes a structure that is substantially the same as the LED package 200 shown in FIG. 6. Since the upper base part 203 is made of a common polymer, the LED package 200-2 also has a merit in that the inner surface 204 of the upper base part 203 has a higher reflectivity than that of FIG. 6.

Alternatively, it is possible to realize more excellent reflection efficiency by making the upper base part 203 of a high reflectivity polymer. Also, further excellent reflection efficiency can be obtained by providing the reflector 230 of FIG. 7 to the inner surface 204 of the upper base part 203.

FIG. 10 is a perspective view illustrating an LED assembly of the invention.

The LED assembly shown in FIG. 10 is used particularly for lighting, and includes a plurality of LED packages 100 and a metal board 130. Each LED package 100 has a structure the same as that illustrated in FIGS. 3 to 5, and the metal board 130 has a structure basically the same as that illustrated in FIG. 4. A circuit pattern (see the reference sign 134 in FIG. 4) is formed on the surface of the metal board 130 to be connected with the terminals (see the reference sign 104 in FIG. 4) of the LED packages 100.

With this arrangement, heat generated from the LED package 100 can be efficiently conducted to metal board 130 through the LED package base (see the reference sign in FIG. 4), thereby preventing heat stress that otherwise may be applied to the LED package 100.

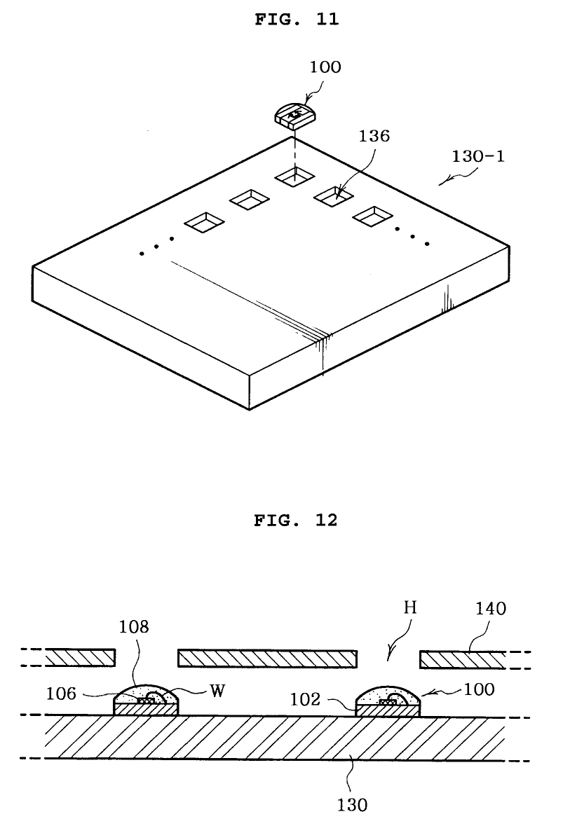

FIG. 11 is a perspective view illustrating an LED assembly according to another embodiment of the invention.

The LED assembly shown in FIG. 11 is used particularly for lighting, and includes a plurality of LED packages 100 (only one is shown) and a metal board 130-1 having a plurality of recesses 136 corresponding to the LED packages 100. Each LED package 100 has a structure the same as that illustrated in FIGS. 3 to 5, and the metal board 130-1 has a structure basically the same as that illustrated in FIG. 5. A circuit pattern (see the reference sign 138 in FIG. 5) is formed on the surface of the metal board 130-1 or the recesses 136 to be connected with the terminals (see the reference sign 104 in FIG. 5) of the LED packages 100.

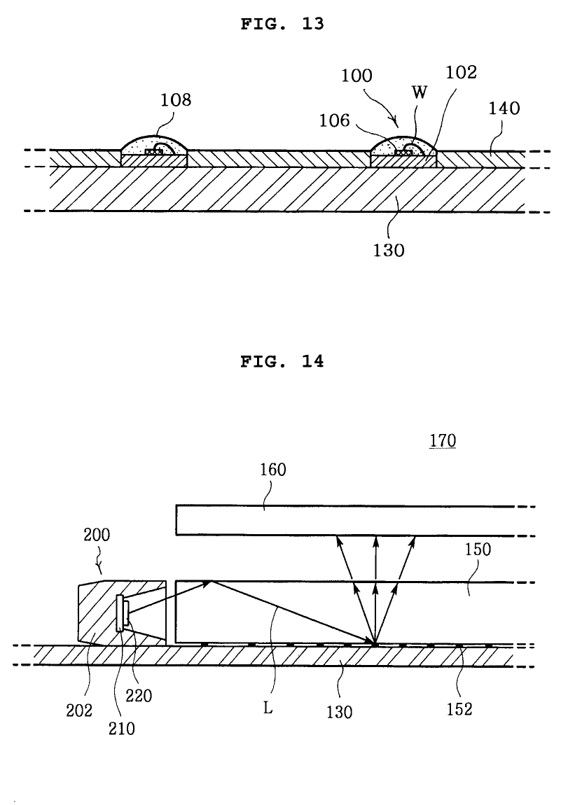

FIGS. 12 and 13 are cross-sectional views illustrating an LED assembly according to further another embodiment of the invention.

Referring to FIGS. 12 and 13, the LED assembly includes a plurality of LED packages 100, a metal board 130 mounted with the LED packages 100 and an upper board 140 having holes H corresponding to the LED packages 100. Here, the LED packages 100 and the metal board 130 are structured substantially the same as those shown in FIG. 10.

With this arrangement, the holes H of the upper board 140 act as reflectors that guide light from the LED chips 106 to emit upward. Accordingly, the LED assembly of this embodiment has substantially the same function as that illustrated in FIG. 11. The upper board 140 is preferably made of a high reflectivity material. For example, the upper board 140 may be made of one selected from high reflectivity polymers and various metals.

FIG. 14 is a side elevation view illustrating an LED assembly according to other embodiment of the invention, shown partially in cross-section.

The LED assembly shown in FIG. 14 is applied to a backlight unit 170. In FIG. 14, an LED package 200 is shown in a cross-section taken along the line 14-14 of FIG. 6, and corresponds to a side view LED package.

The LED assembly of this embodiment is realized by mounting the LED package 200 in plural numbers on the metal board 130 to be arrayed in a direction vertical to the paper of FIG. 14. The metal board 130 of the LED assembly 200 also serves as a circuit board of the backlight unit 170, and the LED packages 200 serve as a light source of the backlight unit 170.

A light guide plate 150 is placed on the board 130, and a scattering pattern 152 such as microstructural features is formed on the underside of the light guide plate 150. With this arrangement, light beams L introduced into the light guide plate 150 from the LED package 200 propagate inside the light guide plate 150, and when scattered upward at the scattering pattern 152, exit the light guide plate 150, thereby backlighting an LCD panel 160 placed above the light guide plate 150.

In this arrangement also, the base 202 of the LED package 200 has excellent thermal conductivity to efficiently conduct heat from the LED chip 220 to the metal board 130, and thus the LED package 200 and the LED chip 220 therein can maintain a suitable temperature.

As described above, the LED package and the LED assembly according to the exemplary embodiments of the invention are provided with the package base made of a thermally conductive polymer, which can improve heat dissipation performance remarkably. Optionally, the reflector arranged around the LED chip can improve the reflecting efficiency of the LED package. Moreover, the LED package may be received at least partially in the metal board to further improve the heat dissipation efficiency.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

What is claimed is:

1. A light emitting diode package comprising:
a base made of a thermally conductive polymer;
a pair of terminals formed on an upper side of the base;
a light emitting diode chip electrically connected to the terminals; and
a transparent encapsulant arranged on the upper side of the base to encapsulate the light emitting diode chip.

2. The light emitting diode package according to claim 1, further comprising a wall extended from a periphery of the upper side of the base beyond the light emitting diode chip to form a recess surrounding the light emitting diode chip, where the transparent encapsulant is filled.

3. The light emitting diode package according to claim 2, further comprising a reflector applied on an inner surface of the wall of the base.

4. The light emitting diode package according to claim 3, wherein the reflector comprises metal.

5. The light emitting diode package according to claim 4, wherein the reflector comprises at least one selected from the group consisting of Ag, Al, Au, Cu, Pd, Pt, Rd and alloys thereof.

6. The light emitting diode package according to claim 4, wherein the reflector comprises a deposit.

7. The light emitting diode package according to claim 6, further comprising an insulating layer formed on a predetermined area in an upper side of the terminals to insulate the reflector from the terminals.

8. The light emitting diode package according to claim 4, wherein the reflector comprises a metal film bonded to an inner surface of the wall of the base.

9. The light emitting diode package according to claim 2, wherein the wall is integral with the base.

10. The light emitting diode package according to claim 2, wherein the wall comprises a separate body bonded to the base.

11. A light emitting diode assembly comprising:
a metal board having a circuit pattern formed on an upper side thereof; and
a light emitting diode package mounted on the upper side of the metal board, the light emitting diode package comprising a base made of a thermally conductive polymer; a pair of terminals formed on an upper side of the base; a light emitting diode chip electrically connected to the terminals; and a transparent encapsulant arranged on the upper side of the base to encapsulate the light emitting diode chip,
wherein the terminals of the light emitting diode package are electrically connected to the circuit pattern.

12. The light emitting diode assembly according to claim 11, wherein the light emitting diode package further comprises a wall extended from a periphery of the upper side of the base beyond the light emitting diode chip to form a recess surrounding the light emitting diode chip, where the transparent encapsulant is filled.

13. The light emitting diode assembly according to claim 12, wherein the light emitting diode package further comprises a reflector applied on an inner surface of the wall of the base.

14. The light emitting diode assembly according to claim 13, wherein the reflector comprises metal.

15. The light emitting diode assembly according to claim 14, wherein the reflector comprises at least one selected from the group consisting of Ag, Al, Au, Cu, Pd, Pt, Rd and alloys thereof.

16. The light emitting diode assembly according to claim 14, wherein the reflector comprises a deposit.

17. The light emitting diode assembly according to claim 16, wherein the reflector comprises an insulating layer formed on a predetermined area in an upper side of the terminals to insulate the reflector from the terminals.

18. The light emitting diode assembly according to claim 14, wherein the reflector comprises a metal film bonded to an inner surface of the wall of the base.

19. The light emitting diode assembly according to claim 12, wherein the wall is integral with the base.

20. The light emitting diode assembly according to claim 12, wherein the wall comprises a separate body bonded to the base.

21. The light emitting diode assembly according to claim 11, wherein the metal board has a recess for receiving at least a part of the light emitting diode package.

22. The light emitting diode assembly according to claim 11, further comprising an upper board attached to the upper side of the metal board, the upper board receiving at least a part of the light emitting diode package to expose the transparent encapsulant.

23. The light emitting diode assembly according to claim 11, wherein the metal board comprises at least a part of a board of a backlight unit on which the light emitting diode assembly is mounted as a light source.
